(19) United States
(12) Patent Application Publication
(10) Pub. No.: US 2026/0052806 A1
(43) Pub. Date: Feb. 19, 2026

(54) MICRO LED DISPLAY CHIP AND METHOD FOR ROUGHENING THE SAME

(71) Applicant: JADE BIRD DISPLAY (SHANGHAI) LIMITED, Shanghai (CN)

(72) Inventors: Jin CAO, Shanghai (CN); Jian GUO, Shanghai (CN)

(73) Assignee: JADE BIRD DISPLAY(SHANGHAI) LIMITED, Shanghai (CN)

(21) Appl. No.: 19/303,382

(22) Filed: Aug. 19, 2025

(30) Foreign Application Priority Data
Aug. 19, 2024 (CN) 202411142854.3

(51) Int. Cl. H10H 20/82; H10H 29/01

(52) U.S. Cl. CPC H10H 20/82; H10H 29/012

(57) ABSTRACT

A micro LED display chip and a method for roughening the same, and the method includes providing a micro LED structure including a light emitting mesa, and the light emitting mesa has a surface including a light emitting surface; forming a sacrificial layer on the light emitting surface; performing a first roughening treatment on a surface of the sacrificial layer, to form a first roughened structure; and performing a second roughening treatment on the surface of the sacrificial layer having the first roughened structure, to remove the sacrificial layer and form a second roughened structure on the light emitting surface. The embodiments of the present disclosure can increase probability of photons'escape and improve light extraction efficiency.

### CROSS-REFERENCE TO RELATED APPLICATIONS

This application claims the benefit of priority to Chinese Patent Application No. 202411142854.3, filed on Aug. 19, 2024 with China National Intellectual Property Administration, and entitled “MICRO LED DISPLAY CHIP AND METHOD FOR ROUGHENING THE SAME”, the entire disclosure of which is incorporated herein by reference.

### FIELD

The present disclosure relates to the field of semiconductor manufacturing, and more particularly, to a micro LED display chip and a method for roughening the same.

### BACKGROUND

With gradual development of display technology, micro light emitting diode (LED) display chips, as semiconductor components having tiny sizes (e.g., less than 50 um) and capable of emitting light, have increasingly become a trend of new display technology due to their low power consumption, long life, high brightness, high contrast and other advantages. Light emitting mesa is an important structure in micro LED display chips, and is particularly valued in light emitting effect thereof.

However, there is such a physical phenomenon that visible light is prone to total reflection at an interface when entering from an optically denser medium to an optically thinner medium, and a light emitting surface of the light emitting mesa has a large difference in refractive index. As a result, it is difficult for light to escape directly from the surface after total reflection. Moreover, even if the light escapes after multiple reflections, there is a problem of excessive light loss, which seriously reduces light extraction efficiency.

There is an urgent need for a method for roughening a micro LED display chip, which can adjust an optical path by roughening a light emitting surface, and can even change a propagation direction of an original total reflection light, to effectively increase probability of photons'escape and improve the light extraction efficiency.

### SUMMARY

The present disclosure provides a micro LED display chip and a method for roughening the same, to increase probability of photons'escape and improve the light extraction efficiency.

Embodiments of the present disclosure provide a method for roughening a micro LED display chip. The method includes providing a micro LED structure including a light emitting mesa, and the light emitting mesa has a surface including a light emitting surface; forming a sacrificial layer on the light emitting surface; performing a first roughening treatment on a surface of the sacrificial layer, to form a first roughened structure; and performing a second roughening treatment on the surface of the sacrificial layer having the first roughened structure, to remove the sacrificial layer and form a second roughened structure on the light emitting surface.

In some embodiments, before performing the first roughening treatment on the surface of the sacrificial layer, the method further includes heating the sacrificial layer to cure the sacrificial layer.

In some embodiments, heating the sacrificial layer is carried out at a temperature between 80° C. and 200° C..

In some embodiments, a method for forming the light emitting mesa includes providing a substrate and forming on a first surface of the substrate a first confinement layer, a quantum well layer and a second confinement layer; etching, from the first surface of the substrate, the second confinement layer, the quantum well layer, and a part of a thickness of the first confinement layer, to obtain a light emitting mesa; and removing the substrate from a second surface of the substrate, and exposing a second surface of the first confinement layer, and the second surface of the substrate is opposite to the first surface of the substrate, and the sacrificial layer is formed on the second surface of the first confinement layer.

In some embodiments, before removing the substrate from the second surface of the substrate, the method for forming the light emitting mesa further includes forming a first bonding layer covering the substrate and the light emitting mesa from the first surface of the substrate; providing a driver chip with a second bonding layer on a first surface thereof; and bonding the first bonding layer and the second bonding layer.

In some embodiments, the method for forming the light emitting mesa further includes forming a microlens on a treated second surface of the first confinement layer.

In some embodiments, performing the first roughening treatment on the surface of the sacrificial layer includes roughening the surface of the sacrificial layer, to form a rough surface from the surface of the sacrificial layer; and performing a first etching on the sacrificial layer, to form the first roughened structure.

In some embodiments, during a process of performing the first etching on the sacrificial layer to form the first roughened structure, the etching is stopped when a bottom of the sacrificial layer exposes the light emitting surface with a predetermined area.

In some embodiments, performing the first etching on the sacrificial layer to form the first roughened structure includes preforming the first etching on the sacrificial layer, until a part of the light emitting surface is exposed and a part of the sacrificial layer is retained, and, a stacked structure of a remaining sacrificial layer and a remaining light emitting surface has a surface roughness greater than or equal to a first predetermined roughness threshold.

In some embodiments, the sacrificial layer is a fluorine-containing photoresist layer; and performing the first etching on the sacrificial layer includes etching the photoresist layer using a reactive gas containing CₓF_{y} and oxygen, to obtain a solid fluorine-based ionic compound, and the formed solid fluorine-based ionic compound is retained on the photoresist layer; and etching the remaining photoresist layer using oxygen, until the part of the light emitting surface is exposed and the part of the sacrificial layer is retained.

In some embodiments, CₓF_{y} is CF₄; and a ratio between a flow rate of CF₄ and a flow rate of oxygen ranges in [2,6].

In some embodiments, the flow rate of CF₄ ranges from 60 sccm to 100 sccm; and the flow rate of oxygen ranges from 15 sccm to 25 sccm.

In some embodiments, before etching the photoresist layer using a reactive gas containing CₓF_{y} and oxygen, the method for roughening a micro LED display chip further includes heating and baking the photoresist layer, until the photoresist layer has a hardness greater than or equal to a predetermined hardness.

In some embodiments, between etching the photoresist layer and etching the remaining photoresist layer using oxygen, and performing the first etching on the photoresist layer further includes monitoring a surface roughness of the photoresist layer with the solid fluorine-based ionic compound on a surface thereof; and performing a second etching on the remaining photoresist layer and the light emitting surface, in response to an increase rate in the surface roughness of the photoresist layer becomes from greater than a first predetermined rate threshold to less than or equal to the first predetermined rate threshold.

In some embodiments, between etching the photoresist layer and etching the remaining photoresist layer using oxygen, performing the first etching on the photoresist layer further includes performing a second etching on the remaining photoresist layer and the light emitting surface, in response to an etching duration of the first etching on the photoresist layer is greater than or equal to a predetermined duration.

In some embodiments, etching the remaining photoresist layer using oxygen includes adjusting an etching selectivity of the photoresist layer and the first confinement layer, and the adjusted etching selectivity falls within a predetermined etching selectivity range; and etching the remaining photoresist layer with the adjusted etching selectivity.

In some embodiments, the predetermined etching selectivity range ranges from 2:1 to 1:2.

In some embodiments, the adjusted etching selectivity is greater than 1:1.

In some embodiments, a ratio of an area of a retained part of the photoresist layer to an area of the photoresist layer before the first etching ranges from 30% to 70%.

In some embodiments, performing the second roughening treatment on the surface of the sacrificial layer having the first roughened structure includes performing a second etching on the light emitting surface using the remaining sacrificial layer as a mask, and after removing the sacrificial layer, a surface roughness of the light emitting surface is greater than or equal to a second predetermined roughness threshold.

The embodiments of the present disclosure further provide a micro LED display chip. The micro LED display chip includes a light emitting mesa including a light emitting surface. The light emitting surface has a roughened structure prepared by the method for roughening a light emitting surface of a micro LED display chip according to any of the above embodiments.

In some embodiments, the roughened structure is a nanoscale microstructure; and the roughened structure has a width ranging from 20 nm to 1000 nm, and/or, a height ranging from 20 nm to 1000 nm.

In some embodiments, the roughened structure has a shape of one or more selected from a group consisting of spherical shape, hemispherical shape, conical shape, pointed-conical shape, cylindrical shape, and rectangular shape.

The embodiments of the present disclosure further provide a micro LED structure. The micro LED structure includes a light emitting mesa having a light emitting surface; and a sacrificial layer disposed on the light emitting surface and having a first roughened structure on a surface thereof.

In some embodiments, the sacrificial layer exposes a part of the light emitting surface.

The embodiments of the present disclosure have the following beneficial effects.

In the embodiments of the present disclosure, by forming a sacrificial layer on a light emitting surface; performing a first roughening treatment on a surface of the sacrificial layer; and performing a second roughening treatment on the surface of the sacrificial layer having a first roughened structure, it is possible to obtain a light emitting surface with a relatively large surface roughness based on the sacrificial layer with a large surface roughness, and realize a roughening treatment of the light emitting surface, which is conducive to adjusting the optical path, and even changing the propagation direction of the original total reflected light, to effectively increase the probability of photons'escape and improve the light extraction efficiency.

Further, by forming the sacrificial layer on the light emitting surface and then performing a first etching on the sacrificial layer, until a part of the light emitting surface is exposed and a part of the sacrificial layer is retained, and a stacked structure of a remaining sacrificial layer and a remaining light emitting surface has a surface roughness greater than or equal to a first predetermined roughness threshold, a sacrificial layer with a relatively large surface roughness can be obtained as a basis for a subsequent etching process. Then, a second etching is performed on the remaining sacrificial layer and the remaining light emitting surface, and after removing the sacrificial layer, a surface roughness of the light emitting surface is greater than or equal to a second predetermined roughness threshold. As a result, it is possible to obtain a light emitting surface with a relatively large surface roughness based on the sacrificial layer with a large surface roughness, and realize a roughening treatment of the light emitting surface, which is conducive to adjusting the optical path, and even changing the propagation direction of the original total reflected light, to effectively increase the probability of photons'escape and improve the light extraction efficiency. In addition, the sacrificial layer is etched by a dry process, which has better morphological controllability and better process stability than a wet roughening process. A process for etching the sacrificial layer is better controlled in process cost, and thus has lower process cost and complexity than that of a roughening process using nanocrystals and nanoparticles as masks.

Further, the sacrificial layer is a photoresist layer. The photoresist layer is etched using a reactive gas containing CₓF_{y} and oxygen, to obtain a solid fluorine-based ionic compound. And, the formed solid fluorine-based ionic compound is retained on the photoresist layer, which can block further etching of the photoresist to effectively form an uneven etched surface with a certain surface roughness. Therefore, after etching the remaining photoresist layer using oxygen, a photoresist layer with a relatively large surface roughness can be obtained as a basis for a subsequent etching process.

Further, before etching the photoresist layer using the reactive gas containing CₓF_{y} and oxygen, the method for roughening a micro LED display chip further includes heating and baking the photoresist layer, until the photoresist layer has a hardness greater than or equal to a predetermined hardness. With the above embodiment, the photoresist layer can be hardened before being roughened, which is conducive to improving controllability of roughened morphology.

Further, surface roughness is monitored for the photoresist layer with the solid fluorine-based ionic compound on a surface thereof; and a second etching is performed on the remaining photoresist layer and the light emitting surface, in response to an increase rate in the surface roughness of the photoresist layer becomes from greater than a first predetermined rate threshold to less than or equal to the first predetermined rate threshold. With the above embodiment, it can be determined to switch to the next step at a right time, based on a characteristic of slow change in roughness after the surface roughness of the photoresist increases to a certain extent, to achieve a better balance between increasing coarsened particle size and improving production efficiency. In addition, an end time of the first etching is determined by monitoring the surface roughness of the photoresist layer, and is determined more accurately according to a specific situation, to further improve controllability of the roughening treatment.

Further, a second etching is performed on the remaining sacrificial layer and the light emitting surface, in response to an etching duration of the first etching on the sacrificial layer is greater than or equal to a predetermined duration. With the above embodiment, it can be determined to switch to the next step at a right time, based on a characteristic of slow change in roughness after the surface roughness of the photoresist increases to a certain extent, to achieve a better balance between increasing coarsened particle size and improving production efficiency. In addition, an end time of the first etching is determined based on a fact that the etching duration of the first etching is greater than or equal to the predetermined duration, and a unified stop standard can be provided to improve feasibility of large-scale mass production.

Further, during etching the remaining photoresist layer using oxygen, an etching selectivity of the photoresist layer and the light emitting surface is adjusted, and the adjusted etching selectivity falls within a predetermined etching selectivity range; and the remaining photoresist layer is etched with the adjusted etching selectivity. With the above embodiment, the roughness after the first etching can be maintained based on the appropriate adjusted etching selectivity.

Further, a ratio of an area of a retained part of the photoresist layer to an area of the photoresist layer before the first etching ranges from 30% to 70%, and a process situation in an intermediate form can be better controlled by monitoring the area of the photoresist.

Further, a microlens is formed, and the roughened light emitting surface can be used as a refractive layer at the light emitting mesa interface, to better change the propagation direction of total reflected light, increase the probability of photons'escape, and improve the light extraction efficiency.

### BRIEF DESCRIPTION OF THE DRAWINGS

FIG. 1 is a schematic view of a total reflection optical path at an interface between optical material layers in the prior art.

FIG. 2 is a schematic flow chart of a method for roughening a micro LED display chip according to an embodiment of the present disclosure.

FIG. 3 to FIG. 10 are schematic structural section views of a device corresponding to various steps in a method for roughening a micro LED display chip according to an embodiment of the present disclosure.

Description of reference numerals.

Substrate 100, buffer layer 101, epitaxial layer 102, light emitting mesa 103, first confinement layer 1031, quantum well layer 1032, second confinement layer 1033, transparent conductive layer 104, passivation layer 105, first photoresist layer 161, first bonding layer 106, first conductive column 107, photoresist layer 108, driver chip 200, conductive connector 201, second bonding layer 206, second conductive column 207, N-type electrode 301, P-type electrode 302, microlens 303.

### DETAILED DESCRIPTION

As the foregoing description, in existing micro LED display chips, the light emitting surface of the light emitting mesa has a large difference in refractive index. As a result, it is difficult for light to escape directly from the surface after total reflection. Moreover, even if the light escapes after multiple reflections, there is a problem of excessive light loss, which seriously reduces light extraction efficiency.

It has been found though research that, in the existing micro LED display chips, the light emitting surface in the light emitting mesa is often a smooth interface, which is prone to a problem of total reflection.

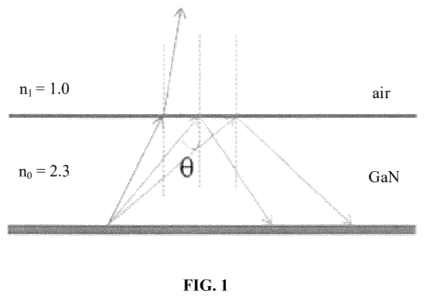

FIG. 1 is a schematic view of a total reflection optical path at an interface between optical material layers in the prior art.

As shown in FIG. 1, as an example, a light emitting surface of a light emitting mesa is made of gallium nitride (GaN), which may have a surface medium with a refractive index, also known as a refractive index n₀ of a material, of 2.3, and air has a refractive index n₁ of approximately 1.0.

Because there is such a physical phenomenon that visible light is prone to total reflection at an interface when entering from an optically denser medium to an optically thinner medium, and the light emitting surface in the light emitting mesa is often a smooth interface, the problem of total reflection is more likely to occur. It has been further found through research that, if the light emitting surface can be roughened, then it will be conducive to adjusting the optical path, and even changing the propagation direction of the original total reflected light, to effectively increase the probability of photons'escape and improve the light extraction efficiency.

In a research direction of roughening treatment, a surface to be treated can be cleaned by a wet roughening treatment method, for example, using potassium hydroxide (KOH) or sulfuric acid (H₂SO₄), to achieve an effect of roughening the surface to be treated.

It has been further found through research that, sizes of coarsened particles obtained by the above wet roughing treatment are relatively large, and thus, depth of roughened morphology and width of obtained particles cannot be effectively controlled, and roughening process is unstable, which can easily lead to deformation and distortion of roughened pattern, which is difficult to meet small size requirements of advanced technology.

In another research direction of roughening treatment, nanocrystals, nanoparticles and other structures can be used as a mask to form a pattern on a chip.

It has been further found through research that, the above roughening treatment method is very costly, has a complex process and a cumbersome post-processing, and is inconvenient.

In the embodiments of the present disclosure, by forming a sacrificial layer on a light emitting surface; performing a first roughening treatment on a surface of the sacrificial layer; and performing a second roughening treatment on the surface of the sacrificial layer having a first roughened structure, it is possible to obtain a light emitting surface with a relatively large surface roughness based on the sacrificial layer with a large surface roughness, and realize a roughening treatment of the light emitting surface, which is conducive to adjusting the optical path, and even changing the propagation direction of the original total reflected light, to effectively increase the probability of photons'escape and improve the light extraction efficiency.

In order to make the above-mentioned purposes, features and beneficial effects of the present disclosure more obvious and understandable, specific embodiments of the present disclosure will be described in detail below in conjunction with the accompanying drawings.

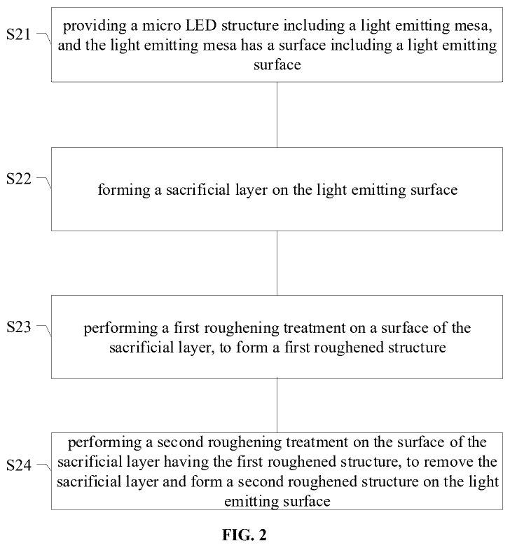

FIG. 2 is a schematic flow chart of a method for roughening a micro LED display chip according to an embodiment of the present disclosure. The method for roughening the micro led display chip may include:
step S21: providing a micro LED structure including a light emitting mesa, and the light emitting mesa has a surface including a light emitting surface;
step S22: forming a sacrificial layer on the light emitting surface;
step S23: performing a first roughening treatment on a surface of the sacrificial layer, to form a first roughened structure; and
step S24: performing a second roughening treatment on the surface of the sacrificial layer having the first roughened structure, to remove the sacrificial layer and form a second roughened structure on the light emitting surface.

Each of the above steps will be illustrated below in conjunction with the accompanying drawings.

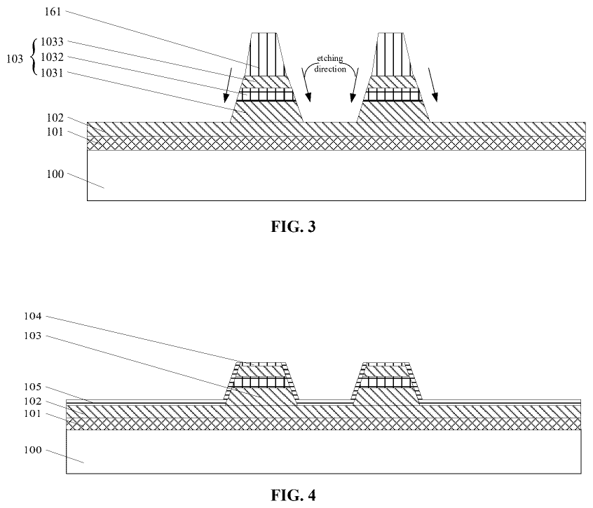

FIG. 3 to FIG. 10 are schematic structural section views of a device corresponding to various steps in a method for roughening a micro LED display chip according to an embodiment of the present disclosure. In specific embodiments as shown in FIG. 3 to FIG. 7, a method for forming the light emitting mesa may include providing a substrate and forming on a first surface of the substrate a first confinement layer, a quantum well layer and a second confinement layer; etching, from the first surface of the substrate, the second confinement layer, the quantum well layer, and a part of a thickness of the first confinement layer, to obtain a light emitting mesa; and removing the substrate from a second surface of the substrate, and exposing a second surface of the first confinement layer, and the second surface of the substrate is opposite to the first surface of the substrate, and the sacrificial layer is formed on the second surface of the first confinement layer.

It should be pointed out that, in the embodiments of the present disclosure, the light emitting mesa may also be formed using other appropriate methods, such as, forming a second confinement layer, a quantum well layer and a first confinement layer on the first surface of the substrate from bottom to top to obtain a light emitting mesa, instead of the method for obtaining the light emitting mesa by inverted etching described above.

It should be pointed out that, the light emitting surface according to the embodiments of the present disclosure is not limited to the first confinement layer, but can also be a light emitting surface of the light emitting mesa formed in other appropriate ways. In the embodiments shown below and in the accompanying drawings, as an example, the second surface of the first confinement layer is used as the light emitting surface, but the present disclosure is not limited hereto.

As shown in FIG. 3, a substrate 100 is provided. A first confinement layer 1031, a quantum well layer 1032 and a second confinement layer 1033 are formed on a first surface of the substrate 100. The second confinement layer 1033, the quantum well layer 1032 and a part of a thickness of the first confinement layer 1031 are etched from the first surface of the substrate 100, to obtain a light emitting mesa 103.

Specifically, the substrate 100 may be provided. A buffer layer 101 may be formed on the substrate 100. And, a material layer of an epitaxial layer 102 may be formed on the buffer layer 101.

In some embodiments, the substrate 100 may, for example, include a sapphire substrate, etc., and have a composition containing alumina (Al₂O₃).

In some other embodiments, the substrate 100 may include a substrate of other appropriate materials, such as, a semiconductor substrate, such as a silicon substrate. The semiconductor substrate may further be made of a material including germanium, silicon germanium, silicon carbide, gallium arsenide or indium gallium. The semiconductor substrate may further be a silicon substrate on an insulator or a germanium substrate on an insulator, or a substrate with an epitaxial layer (Epi layer) grown.

In some embodiments, the epitaxial layer 102 may include one or more selected from a group consisting of the first confinement layer 1031, the quantum well layer 1032, and the second confinement layer 1033.

The first confinement layer 1031 may be an N-type Group III-V compound layer, and correspondingly, the second confinement layer 1033 may be a P-type Group III-V compound layer.

The quantum well layer 1032 may be a layer of a material suitable for forming a quantum well structure, such as, a layer of a Group III-V compound.

It should be pointed out that, the III-V compound layer refers to a material layer formed from a compound of an element selected from a group consisting of Group III elements and of an element selected from a group consisting of Group V elements, and the Group III elements may include, for example, B, Al, Ga, and In, the Group V elements may include N, P, As, and Sb.

In the embodiments of the present disclosure, the Group III-V compound layer may be selected and used according to specific requirements, and specific Group III-V compounds adopted in the first confinement layer 1031, the quantum well layer 1032 and the second confinement layer 1033 may be consistent or inconsistent.

In one specific embodiment, the Group III-V compound layer may be selected from a group consisting of GaN, GaAs and InP.

It should be pointed out that, the epitaxial layer 102 may further include other appropriate layers, such as, a sacrificial layer, or the like, and is not limited in specific structure herein.

In some embodiments, a material layer of a transparent conductive layer 104 (see FIG. 4) may further be formed on the material layer of the epitaxial layer 102, and then, the transparent conductive layer 104 may be etched together with the second confinement layer 1033.

Here, the transparent conductive layer 104 may be made of a material including indium tin oxide (In₂O₅Sn), to improve conductivity property and light emitting effect, and to reduce the ohmic effect.

It should be pointed out that, the material of the transparent conductive layer 104 may also include other appropriate materials, such as, fluorine-doped tin oxide (FTO), and zinc oxide (ZnO).

It should be pointed out that, in some embodiments, it is also possible to form a transparent conductive layer 104 on a top surface of the light emitting mesa 103 after etching the first confinement layer 1031, the quantum well layer 1032, and the second confinement layer 1033 to obtain the light emitting mesa 103. Therefore, in order to illustrate a process of forming the light emitting mesa 103 more clearly, the transparent conductive layer 104 is not shown in FIG. 3. However, this does not constitute a restriction on specific steps and processes for forming the transparent conductive layer 104.

In the embodiment shown in FIG. 3, a patterned first photoresist layer 161 may further be formed. The first photoresist layer 161 covers various light emitting mesas in a light emitting mesa region, and exposes a region between adjacent light emitting mesas.

Then, by using the first photoresist layer 161 to etch the second confinement layer 1033, the quantum well layer 1032 and the first confinement layer 1031, the second confinement layer 1033 and the quantum well layer 1032 in addition to the light emitting mesa can be removed, and a part of a thickness of the first confinement layer 1031 can be removed, to retain the second confinement layer 1033, the quantum well layer 1032, and the first confinement layer 1031 of the light emitting mesa.

As shown in FIG. 4, the first photoresist layer 161 is removed, and a passivation layer 105 is formed. As previously mentioned, the transparent conductive layer 104 can further be formed.

And, the passivation layer 105 may be disposed on sidewall surfaces of various light emitting mesas 103 and a surface of the substrate 100, and top surfaces of the light emitting mesas 103 are exposed.

In some embodiments, the passivation layer 105 can further be formed into covering the substrate 100 and exposing the top surfaces of the light emitting mesas 103. In other words, the passivation layer 105 can cover the sidewall surfaces of the light emitting mesas 103.

And, the passivation layer 105 may be made from a material including a stack of one or more selected from a group consisting of a silicon oxide layer, an alumina layer, a silicon nitride layer, and a polyimide layer.

As shown in FIG. 5, a first bonding layer 106 is formed. The first bonding layer 106 covers the substrate 100 and the light emitting mesa 103 from the first surface of the substrate 100.

Specifically, the first bonding layer 106 may be formed on the substrate 100. A via may be formed in the first bonding layer 106. A first conductive column 107 may be formed in the via.

Specifically, a material layer of the first bonding layer 106 may be formed first, and then, the first bonding layer 106 is etched to form a via. The via of the first bonding layer 106 exposes a light reflection layer 111 on the top surfaces of the light emitting mesas 103 (in a case that a protective layer 105 is formed, the protective layer 105 may be penetrated and the light reflection layer 111 is exposed), and exposes a P-type electrode region.

In some embodiments, the substrate 100 may have one or more regions selected from a group consisting of an N-type electrode region for forming an N-type electrode, a P-type electrode region for forming a P-type electrode, and a display region for forming the light emitting mesas 103. It should be understood that, the substrate 100 may further have other appropriate regions.

And, the first conductive column 107 may be disposed on the light reflection layer 111 on the top surfaces of the light emitting mesas 103, and in the P-type electrode region of the substrate 100.

In one specific embodiment, the first conductive column 107 may be made from a material including a combination of one or more selected from a group consisting of copper, tungsten, aluminum, silver, platinum, and gold.

It should be understood that, a depth of the first conductive column 107 on the top surfaces of the light emitting mesas 103 and a depth of the first conductive column 107 in the P-type electrode region may be consistent.

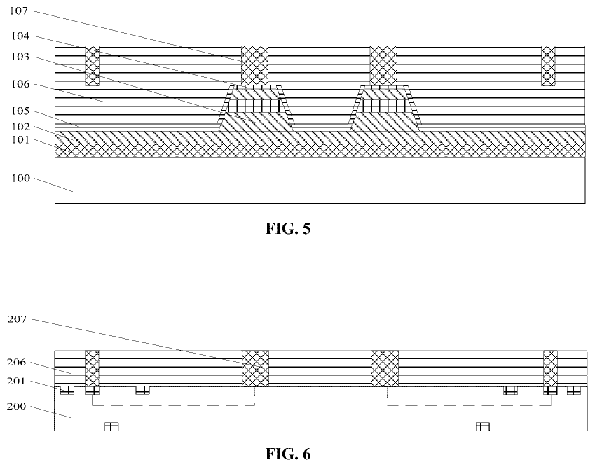

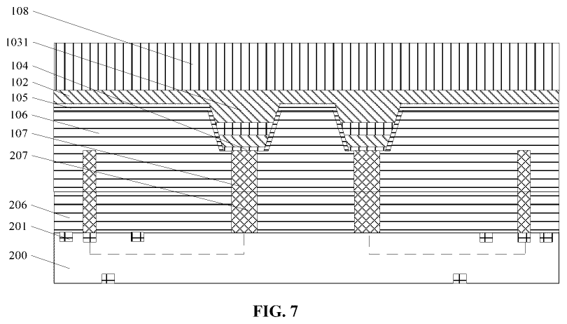

As shown in FIG. 6, a driver chip 200 is provided, and the driver chip 200 has a second bonding layer 206 on a first surface thereof.

Specifically, the driver chip 200 may be formed. A second bonding layer 206 may be formed on the driver chip 200. And, a second conductive column 207 may be formed in the second bonding layer 206.

And, a position of the second conductive column 207 and a position of the first conductive column 107 corresponds one by one.

Here, the driver chip 200 may be, for example, a thin film transistor (TFT) board or an integrated circuit (IC) board.

The driver chip 200 may have a conductive connector 201 therein, for example, may include a conductive interconnecting layer having a wire and a conductive plug.

In one specific embodiment, the second bonding layer 206 may be made from a material including a combination of one or more selected from a group consisting of silicon oxide, alumina, and silicon nitride.

The second conductive column 207 may be made from a material including a combination of one or more selected from a group consisting of copper, tungsten, aluminum, silver, platinum, and gold.

Please refer to FIG. 7, the first bonding layer 106 and the second bonding layer 206 are bonded. The substrate 100 and the buffer layer 101 are removed from the second surface of the substrate 100 (see FIG. 5), and a second surface of the first confinement layer 1031 is exposed. Then, a sacrificial layer is formed on the second surface of the first confinement layer 1031.

And, the second surface of the substrate 100 is opposite to the first surface of the substrate 100.

Specifically, the driver chip 200 and the substrate 100 may be connected by flip bonding, and the first conductive column 107 and the second conductive column 207 are electrically connected in a one to one correspondence.

The first bonding layer 106 and the second bonding layer 206 may be bonded by adopting an appropriate bonding process, to realize flip bonding connection between the driver chip 200 and the substrate 100.

In some embodiments, the sacrificial layer may be a fluorine-containing photoresist (PR) layer 108.

And, the fluorine-containing photoresist, also referred as photoresist containing fluorine-based ions, refers to a material in which fluorine-containing elements and compounds thereof are added into photoresist. On one hand, the fluorine-containing photoresist can increase physical and chemical stability of photoresist, to improve controllability on a process for manufacturing a semiconductor chip. On the other hand, fluorine-based ionic compounds, such as, fluoroalkyl sulfonimide, difluoromethylpyridine, trifluoromethylpyridine derivatives, and the like, are solid and can block further etching of photoresist upon being remained on the photoresist layer.

It should be pointed out that, in some embodiments, the sacrificial layer may also be a layer of other appropriate materials, for example, of a solid fluorine-based ionic compound formed from a reactive gas containing CₓF_{y} and oxygen as an appropriate material.

It should be pointed out that, in the following illustration in conjunction with the accompanying drawings, for the sake of convenience in description, the photoresist layer 108 is used for illustration.

Further, before performing the first roughening treatment on the surface of the sacrificial layer, the method for roughening a micro LED display chip further includes heating the sacrificial layer to cure the sacrificial layer.

Further, heating the sacrificial layer may be carried out at a temperature between 80° C. and 200° C., for example, between 120° C. and 160° C., for example, at 140° C..

In the embodiments of the present disclosure, heating the sacrificial layer to cure the sacrificial layer, and the sacrificial layer can be hardened before being roughened, which is conducive to improving controllability of roughened morphology.

Further, steps for performing the first roughening treatment on the surface of the sacrificial layer may include performing roughening pretreatment on the surface of the sacrificial layer, to form a rough surface from the surface of the sacrificial layer; and performing the first etching on the sacrificial layer, to form the first roughened structure.

In specific embodiments, performing roughening pretreatment on the surface of the sacrificial layer may be realized by plasma bombardment and other methods.

Further, during a process of performing the first etching on the sacrificial layer to form the first roughened structure, the etching is stopped when a bottom of the sacrificial layer exposes the light emitting surface with a predetermined area.

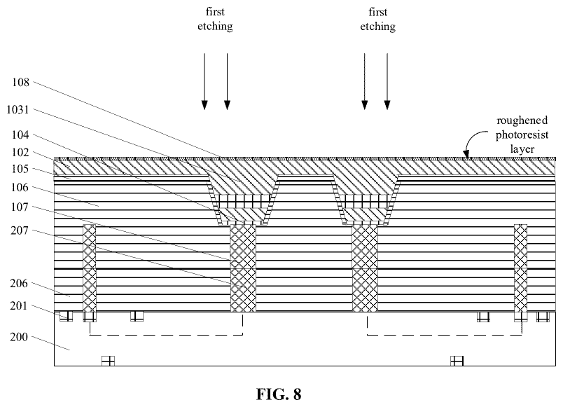

In the embodiments of the present disclosure, by stopping the etching when the bottom of the sacrificial layer exposes the light emitting surface with the predetermined area, effectiveness and reliability of an etching termination position can be effectively ensured. In the specific embodiment shown in FIG. 8, steps for performing the first etching on the sacrificial layer to form the first roughened structure may include preforming the first etching on the sacrificial layer, until a part of the sacrificial layer is retained while a part of the first confinement layer is exposed, and, a stacked structure of a remaining sacrificial layer and a remaining light emitting surface (such as, a remaining first confinement layer) has a surface roughness greater than or equal to a first predetermined roughness threshold.

It should be particularly pointed out that, in the embodiments of the present disclosure, the first roughening treatment may also be performed on the surface of the sacrificial layer by other appropriate means, such as, by plasma bombardment, etc. The appropriate means are not limited to the first etching described above.

Please refer to FIG. 8, a first etching is performed on the photoresist layer 108, to obtain a roughened photoresist layer 108.

Specifically, steps for the first etching on the photoresist layer 108 may include etching the photoresist layer 108 using a reactive gas containing CₓF_{y} and oxygen, to obtain a solid fluorine-based ionic compound, and the formed solid fluorine-based ionic compound is retained on the photoresist layer 108; and etching the remaining photoresist layer 108 using oxygen, until the part of the first confinement layer 1031 is exposed and the part of the photoresist layer 108 is retained.

In the embodiments of the present disclosure, the solid fluorine-based ion compound formed using the photoresist layer 108 is retained on the photoresist layer 108, which can block further etching of the photoresist and effectively form an uneven etched surface with a certain surface roughness. Thus, after etching the remaining photoresist layer 108 using oxygen, a photoresist layer 108 with a relatively large surface roughness can be obtained as a basis for a subsequent etching process.

The surface roughness may include a combination of one or more selected from a group consisting of surface average roughness Ra and surface root mean square roughness Rq.

More specifically, the surface roughness threshold may be expressed by a single parameter, or by a weighted operation value (such as, weighted averaging, weighted summing, etc.) of multiple parameters.

In the embodiments of the present disclosure, by selecting an appropriate parameter to represent the surface roughness, a condition of the second surface of the first confinement layer 1031 can be accurately determined, which helps to determine an appropriate process objective to improve performance of a formed semiconductor structure.

In some embodiments, CₓF_{y} is CF₄; and a ratio between a flow rate of CF₄ and a flow rate of oxygen ranges in [2,6].

It should be pointed out that, the flow rate of CF₄ should not be too small, otherwise it will lead to a too small etching degree of the first etching to meet etching requirements; and the flow rate of CF₄ should not be too large, otherwise it will reduce proportion of oxygen used for the first etching and affects uniformity of the etching.

In one specific embodiment, the flow rate of CF₄ ranges from 60 sccm to 100 sccm, for example, from 70 sccm to 90 sccm, for example, is 80 sccm.

The flow rate of oxygen ranges from 15 sccm to 25 sccm, for example, from 18 sccm to 22 sccm, for example, is 20 sccm.

It should be pointed out that, in the embodiments, CₓF_{y} may also be other appropriate materials, for example, may be a combination of one or more selected from a group consisting of CF₃, CF₂, and CF₄ combined with at least one CF₃ and CF₂.

In some embodiments, before etching the photoresist layer 108 using a reactive gas containing CₓF_{y} and oxygen, the method for roughening a micro LED display chip further includes heating and baking the photoresist layer, until the photoresist layer has a hardness greater than or equal to a predetermined hardness.

In the embodiments, heating and baking the photoresist layer may be carried out at a temperature ranging from 80° C. to 200° C., for example, from 120° C. to 160° C., for example, of 140° C..

In one specific embodiment, the predetermined hardness may be a Moh's hardness of 1.

Moh's hardness, also referred to as Mohs hardness, is a standard for expressing a hardness of an object.

In the embodiments of the present disclosure, before etching the photoresist layer using a reactive gas containing CₓF_{y} and oxygen, by heating and baking the photoresist layer 108 until the hardness of the photoresist layer 108 is greater than or equal to the predetermined hardness, a hardening treatment may be carried out on the photoresist layer 108 before the roughening treatment of the photoresist layer 108, which is conducive to improving controllability on roughened morphology.

Further, an end time of the first etching can further be determined by an appropriate method.

In some embodiments, between etching the photoresist layer 108 and etching the remaining photoresist layer 108 using oxygen, steps for performing the first etching on the photoresist layer 108 may further include monitoring a surface roughness of the photoresist layer 108 with the solid fluorine-based ionic compound on a surface thereof; and performing a second etching on the remaining photoresist layer 108 and the remaining first confinement layer 1031, in response to an increase rate in the surface roughness of the photoresist layer 108 becomes from greater than a first predetermined rate threshold to less than or equal to the first predetermined rate threshold.

In the embodiments, the surface roughness may be monitored by an atomic force microscope (AFM).

Specifically, AFM is an analytical instrument that can be used to study a surface structure of a solid material including insulators. AFM studies the surface structure and properties of a substance by detecting a very weak interaction force between atoms between a surface of a sample to be tested and a micro force-sensitive element. A pair of micro-cantilevers that are extremely sensitive to weak forces are fixed at one end, and a tiny needle tip at the other end are approached to the sample, and at this time, the needle tip will interact with the sample, and an acting force will cause the micro-cantilever to deform or change its motion state. These changes are detected using a sensor while scanning the sample, and force distribution information can be obtained, to obtain surface morphology structure information and surface roughness information at nanoscale resolution.

In the embodiments of the present disclosure, surface roughness is monitored for the photoresist layer 108 with the solid fluorine-based ionic compound on a surface thereof; and a second etching is performed on the remaining photoresist layer 108 and the remaining first confinement layer 1031, in response to an increase rate in the surface roughness of the photoresist layer 108 becomes from greater than a first predetermined rate threshold to less than or equal to the first predetermined rate threshold. With the above embodiment, it can be determined to switch to the next step at a right time, based on a characteristic of slow change in roughness after the surface roughness of the photoresist increases to a certain extent, to achieve a better balance between increasing coarsened particle size and improving production efficiency. In addition, an end time of the first etching is determined by monitoring the surface roughness of the photoresist layer 108, and is determined more accurately according to a specific situation, to further improve controllability of the roughening treatment.

In some other embodiments, between etching the photoresist layer 108 and etching the remaining photoresist layer 108 using oxygen, steps for performing the first etching on the photoresist layer 108 may further include performing a second etching on the remaining photoresist layer 108 and the remaining first confinement layer 1031, in response to an etching duration of the first etching on the photoresist layer 108 is greater than or equal to a predetermined duration.

In the embodiments of the present disclosure, a second etching is performed on the remaining photoresist layer 108 and the remaining first confinement layer 1031, in response to an etching duration of the first etching on the photoresist layer 108 is greater than or equal to a predetermined duration. With the above embodiment, it can be determined to switch to the next step at a right time, based on a characteristic of slow change in roughness after the surface roughness of the photoresist increases to a certain extent, to achieve a better balance between increasing coarsened particle size and improving production efficiency. In addition, an end time of the first etching is determined based on a fact that the etching duration of the first etching is greater than or equal to the predetermined duration, and a unified stop standard can be provided to improve feasibility of large-scale mass production.

Further, steps for etching the remaining photoresist layer 108 using oxygen may include adjusting an etching selectivity of the photoresist layer 108 and the first confinement layer 1031, and the adjusted etching selectivity falls within a predetermined etching selectivity range; and etching the remaining photoresist layer 108 with the adjusted etching selectivity.

In some embodiments, the predetermined etching selectivity range may range from: 2:1 to 1:2.

Specifically, it is possible that an etching rate for the photoresist layer 108 is less than or equal to twice an etching rate for the first confinement layer 1031. It is also possible that the etching rate for the first confinement layer 1031 is less than or equal to twice the etching rate of the photoresist layer 108. It is still possible that the etching rates are between the two.

In the embodiments, by providing the etching selectivity range from: 2:1 to 1:2, a difference between the etching rate for the photoresist layer 108 and the etching rate for the first confinement layer 1031 can be effectively controlled, to avoid etching one of the photoresist layer 108 and first confinement layer 1031 too fast to result in destruction of a roughened surface obtained by the first etching.

In some embodiments, the adjusted etching selectivity is greater than 1:1.

In the embodiments, the etching rate for the photoresist layer 108 may be greater than the etching rate for the first confinement layer 1031, to obtain an adjusted etching selectivity greater than 1:1, and reduction of the photoresist layer 108 can be greater during an etching process, which provides a better basis for a subsequent second etching while maintaining the roughened surface.

In the embodiments of the present disclosure, during etching the remaining photoresist layer 108 using oxygen, an etching selectivity of the photoresist layer 108 and the first confinement layer 1031 is adjusted, and the adjusted etching selectivity falls within a predetermined etching selectivity range; and the remaining photoresist layer 108 is etched with the adjusted etching selectivity. With the above embodiment, the roughness after the first etching can be maintained based on the appropriate adjusted etching selectivity, to provide a better basis for a subsequent second etching.

In some embodiments, a ratio of an area of a retained part of the photoresist layer 108 to an area of the photoresist layer before the first etching ranges from 30% to 70%.

It should be pointed out that, the photoresist layer before the first etching can be regarded as an initial photoresist layer, that is, a photoresist layer formed on the second surface of the substrate.

Specifically, the ratio may range from 30% to 70%, for example, from 40% to 60%, for example, may be 50%.

In the embodiments of the present disclosure, the ratio of the area of the retained part of the photoresist layer to an area of the second surface of the substrate ranges from 30% to 70%, and a process situation in an intermediate form can be better controlled by monitoring the area of the photoresist.

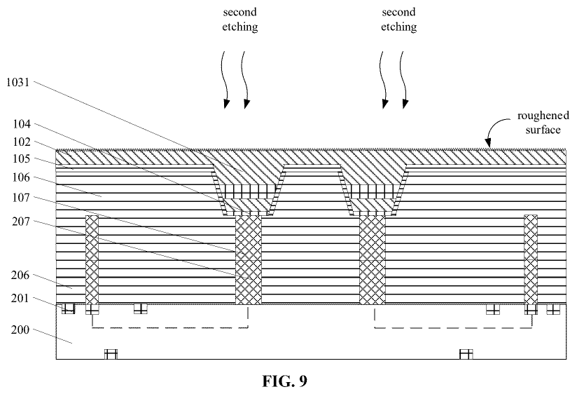

In the specific embodiment shown in FIG. 9, steps for performing the second roughening treatment on the surface of the sacrificial layer having the first roughened structure may include performing a second etching on the remaining first confinement layer using the remaining sacrificial layer as a mask, and after removing the sacrificial layer, a surface roughness of the first confinement layer is greater than or equal to a second predetermined roughness threshold.

It should be particularly pointed out that, in the embodiments of the present disclosure, the second roughening treatment may also be performed on the surface of the sacrificial layer by other appropriate means, for example, by plasma bombardment and other means. The appropriate means are not limited to the second etching described above.

Please refer to FIG. 9, a second etching is performed on the remaining first confinement layer 1031 using the remaining photoresist layer 108 as a mask, and after removing the photoresist layer 108, a surface roughness of the first confinement layer 1031 is greater than or equal to the second predetermined roughness threshold.

In some embodiments, the photoresist layer 108 and the first confinement layer 1031 can be etched together by adjusting the etching selectivity of the photoresist layer 108 and the first confinement layer 1031.

In one specific embodiment, the photoresist layer 108 and the first confinement layer 1031 can be etched using an etching selectivity consistent with the etching selectivity in the steps for etching the remaining photoresist layer using oxygen shown in FIG. 8, to maintain the surface roughness obtained in FIG. 8.

It should be pointed out that, a value can also be selected in the predetermined etching selectivity range disclosed earlier as the etching selectivity in the second etching.

In some other embodiments, the photoresist layer 108 may be used as a mask to mainly etch the first confinement layer 1031, to achieve an effect of increasing the surface roughness under an action of the mask of the photoresist layer 108.

In the embodiments of the present disclosure, by forming the sacrificial layer on the light emitting surface (such as, the first confinement layer 1031) and then performing a first etching on the sacrificial layer (i.e., the photoresist layer 108 shown in FIG. 7 to FIG. 8), until a part of the first confinement layer 1031 is exposed while a part of the sacrificial layer is retained, and a stacked structure of a remaining sacrificial layer and a remaining first confinement layer 1031 has a surface roughness greater than or equal to a first predetermined roughness threshold, a sacrificial layer with a relatively large surface roughness can be obtained as a basis for a subsequent etching process. Then, a second etching is performed on the remaining sacrificial layer and the remaining first confinement layer 1031, and after removing the sacrificial layer, a surface roughness of the first confinement layer 1031 is greater than or equal to a second predetermined roughness threshold. As a result, it is possible to obtain a first confinement layer 1031 with a relatively large surface roughness based on the sacrificial layer with a large surface roughness, and realize a roughening treatment of the light emitting surface, which is conducive to adjusting the optical path, and even changing the propagation direction of the original total reflected light, to effectively increase the probability of photons'escape and improve the light extraction efficiency. In addition, the sacrificial layer is etched by a dry process, which has better morphological controllability and better process stability than a wet roughening process. A process for etching the sacrificial layer is better controlled in process cost, and thus has lower process cost and complexity than that of a roughening process using nanocrystals and nanoparticles as masks.

Further, the roughened structure is a nanoscale microstructure; and the roughened structure has a width ranging from 20 nm to 1000 nm, and/or, a height ranging from 20 nm to 1000 nm.

Specifically, due to formation of the roughened structure, the surface roughness of the first confinement layer 1031 is relatively large. The width of the roughened structure is 20 nm to 1000 nm, and/or, the height of the roughened structure is 20 nm or 1000 nm, and the surface roughness obtained by the roughened structure can be more standardized and controllable.

Further, the roughened structure has a shape of one or more selected from a group consisting of spherical shape, hemispherical shape, conical shape, pointed-conical shape, cylindrical shape, and rectangular shape.

It should be pointed out that, the shape of the roughened structure can be not a standard shape, but can lie between two shapes, for example, an ellipsoid lying between a spherical shape and a hemispherical shape, and the like.

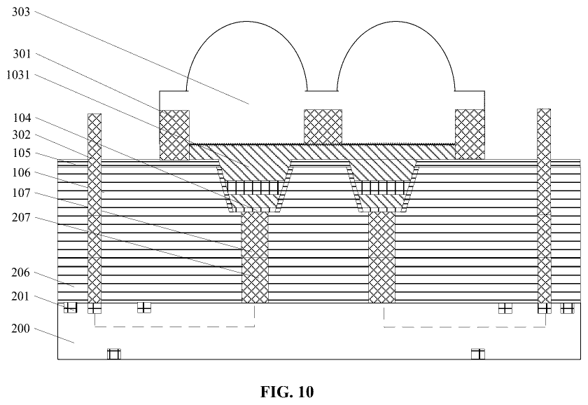

Please refer to FIG. 10, an N-type electrode 301 is formed. A P-type electrode 302 is formed to be electrically connected with the first conductive column 107. And, a microlens (Lens) 303 is formed on a treated second surface of the first confinement layer 1031.

Specifically, the N-type electrode 301 and the P-type electrode 302 may be made of conventional electrode materials, such as, conductive materials, such as appropriate metal materials, such as copper, tungsten, aluminum, platinum, silver, gold, and compound materials of various conductive materials, and the like.

And, the N-type electrode 301 may surround the light emitting mesa 103, and the P-type electrode 302 may be disposed in an edge region.

It should be pointed out that, in the embodiments of the present disclosure, plane layout (i.e., a position relationship shown in a top view) of the N-type electrode 301, the P-Type electrode 302 and the microlens 303 is not limited.

The microlens 303 made be made of conventional lens materials, such as materials with a light transmittance greater than a predetermined light transmittance threshold.

In the embodiments of the present disclosure, the microlens 303 is formed on the treated second surface of the first confinement layer 1031, and the roughened second surface of the first confinement layer 1031, as a refractive layer of the light emitting mesa interface, better changes the propagation direction of the total reflected light, increases the probability of photons'escape, and improves the light extraction efficiency.

In the embodiments of the present disclosure, a micro LED display chip is further disclosed. As shown in FIG. 10, the micro LED display chip may include a light emitting mesa including a light emitting surface. The light emitting surface has a roughened structure prepared by the method for roughening a light emitting surface of a micro LED display chip according described above.

Further, the roughened structure is a nanoscale microstructure; and the roughened structure has a width ranging from 20 nm to 1000 nm, and/or, a height ranging from 20 nm to 1000 nm.

As previously mentioned, by setting the width and/or height of the roughened structure, the surface roughness obtained by the roughened structure can be more standardized and controllable.

Further, the roughened structure has a shape of one or more selected from a group consisting of spherical shape, hemispherical shape, conical shape, pointed-conical shape, cylindrical shape, and rectangular shape.

It should be pointed out that, the shape of the roughened structure can be not a standard shape, but can lie between two shapes, for example, an ellipsoid lying between a spherical shape and a hemispherical shape, and the like.

In the embodiments of the present disclosure, a micro LED structure is further disclosed. As shown in FIG. 8, the micro LED structure may include a light emitting mesa having a light emitting surface (the first confinement layer 1031 shown in FIG. 8); and a sacrificial layer (the photoresist layer 108 shown in FIG. 8) disposed on the light emitting surface, and the sacrificial layer has a first roughened structure on a surface thereof.

Further, the sacrificial layer may expose a part of the light emitting surface.

In the embodiments, by forming the sacrificial layer having the first roughened structure on the surface thereof, the sacrificial layer with a relatively large surface roughness can be used as a basis for a subsequent etching process, which helps to improve the light extraction efficiency.

Please refer to relevant description of the method for roughening a micro LED display chip mentioned above, for more information about the principle, specific implementation and beneficial effects of the micro LED display chip, which will not be repeated here.

It should be understood that, the term “and/or” herein is only an association that describes associated objects, and indicates that there can be three types of relationships. For example, A and/or B can be denoted as: A alone, A and B at the same time, and B alone. In addition, the character “/” herein indicates that related objects before and after is an “or” relationship. As used herein, unless expressly stated otherwise, the term “or” covers all possible combinations, except where infeasible. For example, if it is stated that a part may include A or B, then, unless expressly stated otherwise or infeasible, the part may include A, or B, or A and B. As a second example, if it is stated that a part may include A, B or C, then, unless expressly stated otherwise or infeasible, the part may include A, or B, or C, or A and B, or A and C, or B and C, or A and B and C.

The “plurality”herein refers to two or more.

Relational terms herein, such as, first, second, etc., are used only to distinguish an entity or operation from another entity or operation, without requiring or implying any actual relationship or sequence between those entities or operations. In addition, the words “including”, “having” and “containing” and other similar forms are intended to be equivalent in meaning and be open-ended, and item or items following any one of these words is not meant to be an exhaustive listing of such item or items, or to be limited to only the listed item or items.

It should be pointed out that, the sequence number of each step in the embodiments does not represent limitation of the execution order of each step.

In the foregoing specification, the embodiments have been described with reference to numerous specific details that can vary depending on the implementation. Certain changes and modifications may be made to the described embodiments. Other embodiments are clear in the art from consideration of the specification and practice of the present application disclosed herein. The description and examples are intended to be considered exemplary only, and a true scope and spirit of the present application are indicated by the following claims. The sequence of steps shown in figures is also intended for illustrative purposes only and is not intended to be limited to any particular sequence of steps. Therefore, it is understood that these steps can be performed in a different sequence while implementing the same method.

In the drawings and specification, exemplary embodiments have been disclosed. However, many changes and modifications can be made to these embodiments. Therefore, although specific terms are employed, they are used only in a generic and descriptive sense and not for a purpose of limitation.

Although the present disclosure is disclosed as above, the present disclosure is not limited hereto. Various changes and modifications may be made without departing from the spirit and scope of the present disclosure. Therefore, the scope of protection of the present disclosure shall be subject to the scope limited by the claims.

What is claimed is:

1. A method for roughening a light emitting surface of a micro LED display chip, comprising:
providing a micro LED structure comprising a light emitting mesa, and the light emitting mesa has a surface comprising a light emitting surface;
forming a sacrificial layer on the light emitting surface;
performing a first roughening treatment on a surface of the sacrificial layer, to form a first roughened structure; and
performing a second roughening treatment on the surface of the sacrificial layer having the first roughened structure, to remove the sacrificial layer and form a second roughened structure on the light emitting surface.

2. The method for roughening a light emitting surface of a micro LED display chip according to claim 1, wherein before performing the first roughening treatment on the surface of the sacrificial layer, the method further comprises heating the sacrificial layer at a temperature between 80° C. and 200° C. to cure the sacrificial layer.

3. The method for roughening a light emitting surface of a micro LED display chip according to claim 1, wherein a method for forming the light emitting mesa comprises:
providing a substrate and forming on a first surface of the substrate a first confinement layer, a quantum well layer and a second confinement layer;
etching, from the first surface of the substrate, the second confinement layer, the quantum well layer, and a part of a thickness of the first confinement layer, to obtain the light emitting mesa; and
removing the substrate from a second surface of the substrate, and exposing a second surface of the first confinement layer,
wherein the second surface of the substrate is opposite to the first surface of the substrate; and
wherein the sacrificial layer is formed on the second surface of the first confinement layer.

4. The method for roughening a light emitting surface of a micro LED display chip according to claim 3, wherein before removing the substrate from the second surface of the substrate, the method for forming the light emitting mesa further comprises:
forming a first bonding layer covering the substrate and the light emitting mesa from the first surface of the substrate;
providing a driver chip with a second bonding layer on a first surface thereof; and
bonding the first bonding layer and the second bonding layer.

5. The method for roughening a light emitting surface of a micro LED display chip according to claim 3, wherein the method for forming the light emitting mesa further comprises:
forming a microlens on a treated second surface of the first confinement layer.

6. The method for roughening a light emitting surface of a micro LED display chip according to claim 1, wherein performing the first roughening treatment on the surface of the sacrificial layer comprises:
performing a roughening pretreatment on the surface of the sacrificial layer, to form a rough surface from the surface of the sacrificial layer; and
performing a first etching on the sacrificial layer, to form the first roughened structure.

7. The method for roughening a light emitting surface of a micro LED display chip according to claim 6, wherein during a process of performing the first etching on the sacrificial layer to form the first roughened structure, the etching is stopped when a bottom of the sacrificial layer exposes the light emitting surface with a predetermined area.

8. The method for roughening a light emitting surface of a micro LED display chip according to claim 6, wherein performing the first etching on the sacrificial layer to form the first roughened structure comprises:
preforming the first etching on the sacrificial layer, until a part of the light emitting surface is exposed and a part of the sacrificial layer is retained, wherein, a stacked structure of a remaining sacrificial layer and a remaining light emitting surface has a surface roughness greater than or equal to a first predetermined roughness threshold.

9. The method for roughening a light emitting surface of a micro LED display chip according to claim 8, wherein the sacrificial layer is a fluorine-containing photoresist layer; and performing the first etching on the sacrificial layer comprises:
etching the photoresist layer using a reactive gas containing CₓF_{y} and oxygen, to obtain a solid fluorine-based ionic compound, wherein a formed solid fluorine-based ionic compound is retained on the photoresist layer; and
etching a remaining photoresist layer using oxygen, until the part of the light emitting surface is exposed and the part of the sacrificial layer is retained.

10. The method for roughening a light emitting surface of a micro LED display chip according to claim 9, wherein CₓF_{y} is CF₄; and a ratio between a flow rate of CF₄ and a flow rate of oxygen ranges in [2,6].

11. The method for roughening a light emitting surface of a micro LED display chip according to claim 9, wherein before etching the photoresist layer using the reactive gas containing CₓF_{y} and oxygen, the method for roughening a light emitting surface of a micro LED display chip further comprises:
heating and baking the photoresist layer, until the photoresist layer has a hardness greater than or equal to a predetermined hardness.

12. The method for roughening a light emitting surface of a micro LED display chip according to claim 9, wherein between etching the photoresist layer and etching the remaining photoresist layer using oxygen, performing the first etching on the photoresist layer further comprises:
monitoring a surface roughness of the photoresist layer with the solid fluorine-based ionic compound on a surface thereof; and
performing a second etching on the remaining photoresist layer and the light emitting surface, in response to an increase rate in the surface roughness of the photoresist layer becomes from greater than a first predetermined rate threshold to less than or equal to the first predetermined rate threshold, or
performing a second etching on the remaining photoresist layer and the light emitting surface, in response to an etching duration of the first etching on the photoresist layer is greater than or equal to a predetermined duration.

13. The method for roughening a light emitting surface of a micro LED display chip according to claim 9, wherein etching the remaining photoresist layer using oxygen comprises:
adjusting an etching selectivity of the photoresist layer and the light emitting surface, and an adjusted etching selectivity falls within a predetermined etching selectivity range; and
etching the remaining photoresist layer with the adjusted etching selectivity,
wherein the predetermined etching selectivity range ranges from 2:1 to 1:2, and/or
wherein the adjusted etching selectivity is greater than 1:1.

14. The method for roughening a light emitting surface of a micro LED display chip according to claim 9, wherein a ratio of an area of a retained part of the photoresist layer to an area of the photoresist layer before the first etching ranges from 30% to 70%.

15. The method for roughening a light emitting surface of a micro LED display chip according to claim 1, wherein performing the second roughening treatment on the surface of the sacrificial layer having the first roughened structure comprises:
performing a second etching on the light emitting surface using a remaining sacrificial layer as a mask, and after removing the sacrificial layer, a surface roughness of the light emitting surface is greater than or equal to a second predetermined roughness threshold.

16. A micro LED display chip, comprising:
a light emitting mesa comprising a light emitting surface, and the light emitting surface has a roughened structure prepared by the method for roughening a light emitting surface of a micro LED display chip according to claim 1.

17. The micro LED display chip according to claim 16, wherein the roughened structure is a nanoscale microstructure;
wherein the roughened structure has a width ranging from 20 nm to 1000 nm, and/or, a height ranging from 20 nm to 1000 nm.

18. The micro LED display chip according to claim 16, wherein the roughened structure has a shape of one or more selected from a group consisting of spherical shape, hemispherical shape, conical shape, pointed-conical shape, cylindrical shape, and rectangular shape.

19. A micro LED structure, comprising:
a light emitting mesa having a light emitting surface; and
a sacrificial layer disposed on the light emitting surface and having a first roughened structure on a surface thereof.

20. The micro LED structure according to claim 19, wherein the sacrificial layer exposes a part of the light emitting surface.
